(19) United States
(12) Patent Application Publication
(10) Pub. No.: US 2003/0056727 A1
(43) Pub. Date: Mar. 27, 2003

(54) Method of depositing thin films and apparatus for depositing the same

(76) Inventors: Tsang Jung Lin, Chungli City (TW); Chao-Yuan Huang, Hsinchu (TW)

Correspondence Address: BIRCH STEWART KOLASCH & BIRCH, PO BOX 747, FALLS CHURCH, VA, 22040-0747, US

(21) Appl. No.: 10/035,180

(22) Filed: Jan. 4, 2002

(30) Foreign Application Priority Data
Sep. 24, 2001 (TW) 90123435

(51) Int. Cl. C23C 16/00

(52) U.S. Cl. 118/719

(57) ABSTRACT

A method of depositing thin films has steps of: providing a physical vapor deposition (PVD) vacuum reactor to deposit a first layer; providing at least a metal-organic chemical vapor deposition (MOCVD) vacuum reactor to deposit a second layer on the first layer; and providing a radio frequency (RF) plasma treatment reactor to perform plasma treatment on the second layer.

### BACKGROUND OF THE INVENTION

1. Field of the Invention

The present invention relates to a method of depositing a Ti/TiN thin film and an apparatus for forming the same and, more particularly, to an apparatus comprising a plasma treatment reactor for depositing a TiN thin film.

2. Description of the Related Art

Titanium (Ti) and titanium nitride (TiN) are refractory materials with metallic conductivity and characteristics of thermal stability, excellent mechanical strength and good resistance to corrosion. In the manufacture of very large scale integrated (VLSI) circuitry, Ti and TiN function as, for example, adhesion layers and diffusion barriers. In addition, Ti/TiN bilayers can be formed on a silicon substrate, where the Ti functions as a getter for oxygen at the silicon interface so as to provide a lower and more stable contact resistance. Conventionally, TiN thin film is mainly prepared by physical vapor deposition (PVD) that uses reactive sputtering to form the TiN thin film on the silicon substrate or on the sidewall of a contact hole. However, sputtering produces film with poor step coverage and having columnar structures. In order to solve the problems associated with PVD, chemical vapor deposition (CVD) is employed to deposit the TiN thin film. Generally, CVD for forming Ti-based materials is classified into two types. One type is a method of using inorganic metal-halogen compounds, for example, TiCl₄/NH₃ as the precursor. This method may, however, form corroded impurities and particles in the thin film. The other method uses organic metal compounds as the precursor, for example, TDMAT and TDEAT, referred to as metal-organic CVD (MOCVD).

At present, in fabricating the Ti/TiN thin film, a Ti thin film is sputtered and a TiN thin film is then deposited on the TiN thin film by MOCVD. Thereafter, plasma treatment is required to remove carbon and hydrogen impurities existing in the organic precursor. This also reduces the thickness of the TiN thin film and decreases the resistance of the TiN thin film. FIG. 1 is a schematic diagram showing an apparatus 10 for depositing the Ti/TiN thin film according to the prior art. The apparatus 10 comprises a plurality of wafer-loading/wafer-unloading chambers 12, a PVD vacuum reactor 14, a first MOCVD vacuum reactor 161, a second MOCVD vacuum reactor 162, a cooling chamber 18 and a robotic transporting 20. In depositing the Ti/TiN thin film in the apparatus 10, a prepared wafer is loaded in the wafer-loading chamber 12, and then the prepared wafer is transported to the PVD vacuum reactor 14 by the robotic transporting 20 to deposit a Ti thin film on the prepared wafer. Next, the prepared wafer is transported to the first MOCVD vacuum reactor 161 by the robotic transporting 20 to deposit a first TiN thin film on the Ti thin film, and then a first plasma treatment is performed on the first TiN thin film. Thereafter, the prepared wafer is transported to the second MOCVD vacuum reactor 162 by the robotic transporting 20 to deposit a second TiN thin film on the first TiN thin film, and then a second plasma treatment is performed on the second TiN thin film. Finally, using the robotic transporting 20, the prepared wafer is transported to the cooling chamber 18 to cool the prepared wafer, and then transported to the wafer-unloading chamber 12.

However, two steps of depositing TiN thin film and two steps of plasma treatments are required in the two MOCVD vacuum reactors 161 and 162 respectively, thus pipes of organic precursors and pipes of plasma reacting gases are necessarily disposed in the two MOCVD vacuum reactors 161 and 162 respectively. This makes the MOCVD vacuum reactors 161 and 162 more complicated and expensive. Also, since the plasma treatment is very time-consuming, two steps of plasma treatment prolong the process time of depositing the TiN thin film, resulting in a decrease in the yield of the apparatus 10. Thus, a novel method and a corresponding apparatus solving the aforementioned problems are called for.

### SUMMARY OF THE INVENTION

The present invention provides a method of depositing Ti/TiN thin film by using an apparatus that uses a radio frequency (RF) treatment reactor to replace the plasma treatment in the MOCVD vacuum reactor.

The method of depositing thin films has steps of: providing a physical vapor deposition (PVD) vacuum reactor to deposit a first layer; providing at least a metal-organic chemical vapor deposition (MOCVD) vacuum reactor to deposit a second layer on the first layer; and providing a radio frequency (RF) plasma treatment reactor to perform plasma treatment on the second layer.

Accordingly, it is an object of the invention to provide the RF plasma treatment reactor to reduce the time that the prepared wafer stays in the MOCVD vacuum reactor.

It is another object of the invention to increase the throughput of the Ti/TiN thin film.

Yet another object of the invention is to selectively use equipment relating to plasma treatment in the MOCVD vacuum reactor to decrease the equipment cost.

These and other objects of the present invention will become readily apparent upon further review of the following specification and drawings.

### BRIEF DESCRIPTION OF THE DRAWINGS

FIG. 1 is a schematic diagram showing an apparatus for depositing the Ti/TiN thin film according to the prior art.

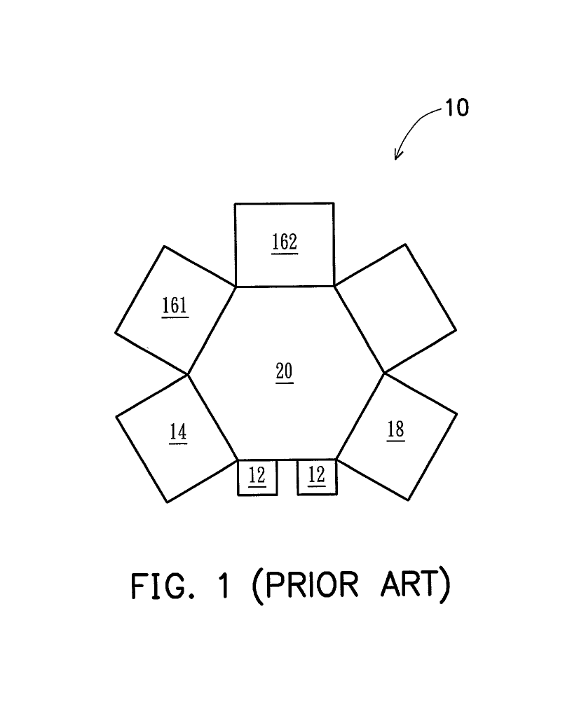

FIG. 2A is a sectional diagram showing the Ti/TiN thin film in a contact hole structure.

FIG. 2B is a sectional diagram showing the Ti/TiN thin film in a via structure

FIG. 3 is a schematic diagram showing an apparatus for depositing the Ti/TiN thin film according to the present invention.

Similar reference characters denote corresponding features consistently throughout the attached drawings.

### DETAILED DESCRIPTION OF THE PREFERRED EMBODIMENTS

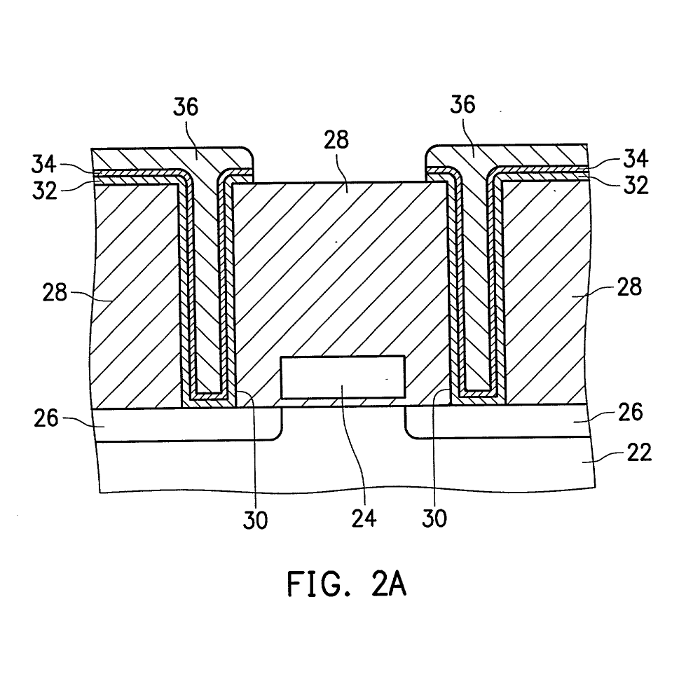

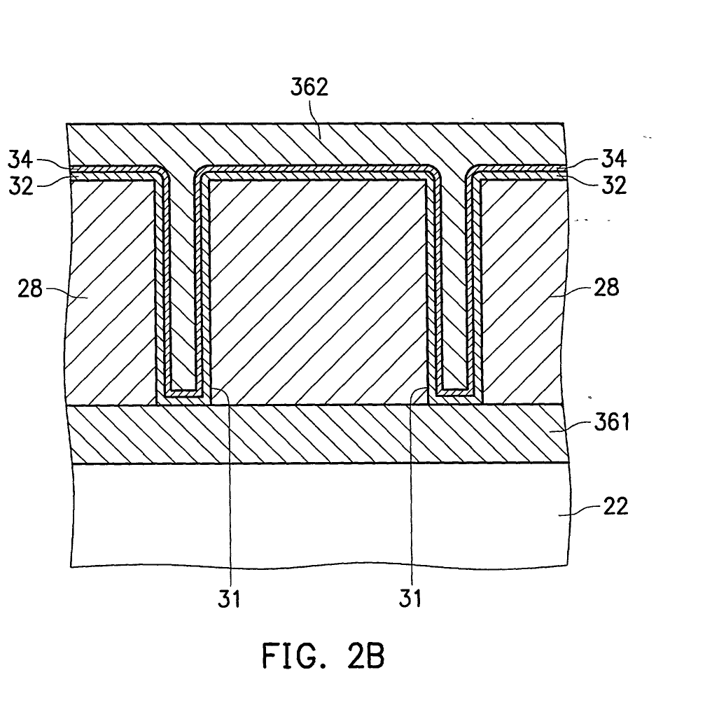

The present invention provides a method of depositing Ti/TiN thin film and a corresponding apparatus for forming the same, in which a radio frequency (RF) reactor is disposed to function as a plasma treatment to replace the step of plasma treatment in the conventional MOCVD vacuum reactor. In the preferred embodiment, the apparatus is used to deposit a Ti/TiN thin film that may serve as an adhesion layer and a diffusion barrier layer. FIG. 2A is a sectional diagram showing the Ti/TiN thin film in a contact hole structure. A semiconductor silicon substrate 22 comprises a gate electrode 24, a source/drain region 26, an inter-metal dielectric (IMD) layer 28, and a contact hole 30 passing through the ILD layer 28 to expose the source/drain region 26. In addition, a Ti thin film 32 is deposited on the bottom and sidewall of the contact hole 30, a TiN thin film 34 is deposited on the Ti thin film 32, and a metal wiring layer 36 is formed on the TiN thin film to fill the contact hole 30. The Ti/TiN thin film 32 and 34 are used as adhesion layers to reduce the contact resistance, and also used as diffusion barrier layers to prevent inter diffusion between the metal wiring layer 36 and the silicon substrate 22.

FIG. 2B is a sectional diagram showing the Ti/TiN thin film in a via structure. The semiconductor substrate 22 has a first metal wiring layer 361, an IMD layer 28, and a plurality of vias 31 passing through the IMD layer 28 to expose the first metal wiring layer 361. A Ti thin film 32 is deposited on the bottom and sidewall of the via 31, a TiN thin film 34 is deposited on the Ti thin film 32, and a second metal wiring layer 362 is deposited on the TiN thin film to fill the via 31.

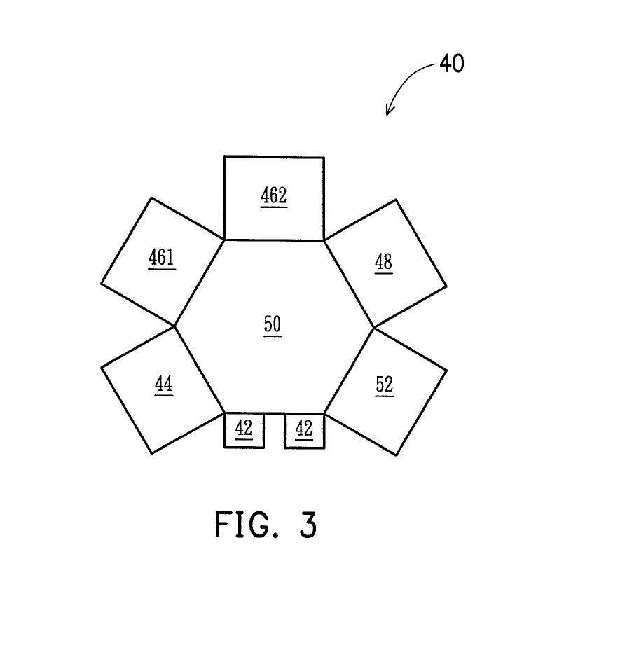

FIG. 3 is a schematic diagram showing an apparatus 40 for depositing the Ti/TiN thin film 32 and 34 according to the present invention. In the deposition of the Ti/TiN thin film 32 and 34, sputtering is used to deposit the Ti thin film 32, and then MOCVD is used to deposit the TiN thin film 34, and thereafter plasma treatment is employed to remove the carbon/hydrogen impurities existing in the organic precursors. The plasma treatment also reduces the thickness of the TiN thin film 34, increases the density of the TiN thin film 34 and decreases the resistivity of the TiN thin film 34. Accordingly, the apparatus 40 comprises a wafer-loading chamber 42, a wafer-unloading chamber 42, a PVD vacuum reactor 44, a first MOCVD vacuum reactor 461, a second MOCVD vacuum reactor 462, an RF plasma treatment reactor 48, a cooling chamber 52, and a robotic transporting system 50.

In depositing the Ti/TiN thin film 32 and 34, a prepared wafer is loaded in the wafer-loading chamber 42, and then the prepared wafer is transported to the PVD vacuum reactor 44 by the robotic transporting system 50 to deposit a Ti thin film 32 on the prepared wafer. Next, the prepared wafer is transported to the first MOCVD vacuum reactor 461 by the robotic transporting system 50 to perform a first-step deposition of the TiN thin film 34 on the Ti tin film 32, and then a first plasma treatment can be selectively performed on the TiN thin film 34. Thereafter, the prepared wafer is transported to the second MOCVD vacuum reactor 462 by the robotic transporting system 50 to perform a second-step deposition of the TiN thin film 34, and then a second plasma treatment can be selectively performed on the TiN thin film 34. Finally, using the robotic transporting system 50, the prepared wafer is transported to the cooling chamber 52 to cool down the prepared wafer, and then transported to the wafer-unloading chamber 42.

In order to promote the depositing efficiency, the RF plasma treatment reactor 48 is selectively employed to replace the first/second plasma treatments in the first/second MOCVD vacuum reactors 461 and 462. For example, when the first-step deposition of the TiN thin film 34 is completed in the first MOCVD vacuum reactor 461, the prepared wafer can be transported to the RF plasma treatment reactor 48 to perform the first plasma treatment. Also, at the same time, another prepared wafer can be transported to the first MOCVD vacuum reactor 461 to perform the first-step deposition of the TiN thin film 34. Similarly, the RF plasma treatment reactor 48 is provided when the second-step deposition of the TiN thin film 34 is completed in the second MOCVD vacuum reactor 462. It is noted that the operational sequence between the RF plasma treatment reactor 48, the first MOCVD vacuum reactor 461 and the second MOCVD reactor 462 depends on process requirements.

Compared with the prior art, in the apparatus 40 of the present invention, the time-consuming plasma treatment is performed in the RF plasma treatment reactor 48 to reduce the time that the prepared wafer stays in the first MOCVD vacuum reactor 461 and the second MOCVD reactor 462. Thus, the throughput of the Ti/TiN thin film is increased in the apparatus 40. Also, since the RF plasma treatment reactor 48, having a simple structure, replaces the plasma treatment equipment relating to plasma treatment in the MOCVD vacuum reactors 461 and 462 can be omitted to decrease the equipment cost of the MOCVD vacuum reactors 461 and 462.

In another preferred embodiment, the apparatus 40 can be applied to the deposition of Ta/TaN thin film. The Ta thin film is deposited in the PVD vacuum reactor 44, the first-step deposition of the TaN thin film is performed in the first MOCVD vacuum reactor 461, and the second-step deposition of the TaN thin film is performed in the second MOCVD vacuum reactor 462.

It is to be understood that the present invention is not limited to the embodiments described above, but encompasses any and all embodiments within the scope of the following claims.

What is claimed is:

1. A method of depositing thin films, comprising steps of:
providing a physical vapor deposition (PVD) vacuum reactor to deposit a first layer;
providing at least a metal-organic chemical vapor deposition (MOCVD) vacuum reactor to deposit a second layer on the first layer; and
providing a radio frequency (RF) plasma treatment reactor to perform plasma treatment on the second layer.

2. The method according to claim 1, wherein the MOCVD vacuum reactor is employed to perform deposition and plasma treatment.

3. The method according to claim 1, wherein the RF plasma treatment reactor can replace the plasma treatment in the MOCVD vacuum reactor.

4. The method according to claim 1, wherein the method is used for depositing Ti/TiN thin film.

5. The method according to claim 4, wherein the PVD vacuum reactor is used to deposit a Ti thin film.

6. The method according to claim 4, wherein the MOCVD vacuum reactor is used to deposit a TiN thin film.

7. The method according to claim 1, wherein the method is used for depositing Ta/TaN thin film.

8. The method according to claim 7, wherein the PVD vacuum reactor is used to deposit a Ta thin film.

9. The method according to claim 7, wherein the MOCVD vacuum reactor is used to deposit a TaN thin film.

10. An apparatus for deposition comprising:
a physical vapor deposition (PVD) vacuum reactor for depositing a first layer;
at least a metal-organic chemical vapor deposition (MOCVD) vacuum reactor for depositing a second layer on the first layer; and
a radio frequency (RF) treatment reactor for performing plasma treatment on the second layer.

11. The apparatus according to claim 10, further comprising a wafer-loading chamber, a wafer-unloading chamber, a cooling chamber and a robotic transporting system.

12. The apparatus according to claim 10, wherein the MOCVD vacuum reactor is employed to perform deposition and plasma treatment.

13. The apparatus according to claim 12, wherein the RF plasma treatment reactor can replace the plasma treatment in the MOCVD vacuum reactor.

14. The apparatus according to claim 10, wherein the apparatus is used for depositing Ti/TiN thin film.

15. The apparatus according to claim 14, wherein the PVD vacuum reactor is used to deposit the Ti thin film.

16. The apparatus according to claim 14, wherein the MOCVD vacuum reactor is used to deposit the TiN thin film.

17. The apparatus according to claim 10, wherein the apparatus is used for depositing Ta/TaN thin film.

18. The apparatus according to claim 17, wherein the PVD vacuum reactor is used to deposit the Ta thin film.

19. The apparatus according to claim 17, wherein the MOCVD vacuum reactor is used to deposit the TaN thin film.
